(19) United States
(12) Patent Application Publication
(10) Pub. No.: US 2023/0128852 A1
(43) Pub. Date: Apr. 27, 2023

(54) SILSESQUIOXANE DERIVATIVE AND USE THEREOF

(71) Applicants: TOAGOSEI CO., LTD., Tokyo (JP); NAGOYA INSTITUTE OF TECHNOLOGY, Nagoya-shi, Aichi (JP)

(72) Inventors: Yoshiaki IWASE, Nagoya-shi (JP); Yuji IWAMOTO, Nagoya-shi (JP); Sawao HONDA, Nagoya-shi (JP); Yusuke DAIKO, Nagoya-shi (JP); Yusuke KAKUTANI, Nagoya-shi (JP)

(73) Assignees: TOAGOSEI CO., LTD., Tokyo (JP); NAGOYA INSTITUTE OF TECHNOLOGY, Nagoya-shi, Aichi (JP)

(21) Appl. No.: 17/796,128

(22) PCT Filed: Jan. 28, 2021
(86) PCT No.: PCT/JP2021/003072

§ 371 Date: Jul. 28, 2022

(30) Foreign Application Priority Data
Jan. 28, 2020 (JP) 2020-011975

(51) Int. Cl. C08G 77/20; C08G 77/12; C08G 77/18; C08K 3/38; H01L 23/373

(52) U.S. Cl. CPC C08G 77/20; C08G 77/12; C08G 77/18; C08K 3/38; H01L 23/3737; C08K 2003/385; C08K 2201/005; C08K 2201/001

(57) ABSTRACT

A silsesquioxane derivative that can further contribute to improving heat conductivity. The silsesquioxane derivative represented in the following formula forms a matrix having exceptional heat conductivity due to curing.

[C5]

[SiO_{4/2}]ₛ[R¹—SiO_{3/2}]ₜ[R²—SiO_{3/2}]ᵤ[H—SiO_{3/2}]ᵥ[R³₂—SiO_{2/2}]_{w}[H,R⁴₂—SiO_{1/2}]ₓ[R⁵₃—SiO_{1/2}]_{y} (1)

[in the formula, R¹ is a hydrosilylation-reactive organic group having a carbon-carbon unsaturated bond and having 2 to 30 carbon atoms, R², R³, R⁴ and R⁵ are each independently at least one selected from the group consisting of an alkyl group having 1 to 10 carbon atoms, an aryl group having 5 to 10 carbon atoms and an aralkyl group having 6 to 10 carbon atoms, t, u, w and x are a positive number, and s, v and y are 0 or a positive number].

### TECHNICAL FIELD

The present specification relates to silsesquioxane derivatives and use thereof.

### CROSS REFERENCE TO RELATED APPLICATIONS

This application is a related application of Japanese Patent Application No. 2020-011975, which is a Japanese patent application filed on Jan. 28, 2020, and claims priority based on this Japanese application, all contents described in this Japanese application are incorporated herein by reference.

### BACKGROUND ART

In recent years, semiconductor products such as power modules have been required to have higher heat dissipation. As a heat dissipation element for this purpose, an insulating and highly thermally conductive composite material containing a thermosetting resin and a thermally conductive filler such as a ceramic has been focused on.

Various attempts have been made in order to increase the thermal conductivity of such composite materials (Non Patent Literature 1). One is to increase the thermal conductivity of the resin itself using, for example, a matrix in which a silicone or epoxy resin is used as a matrix resin. In addition, in order to further increase the thermal conductivity of such a matrix resin, a ceramic filler such as alumina or aluminum nitride may be mixed in as a thermally conductive filler.

On the other hand, modification of the matrix resin is also being examined. For example, it has been attempted to introduce a highly ordered structure into an epoxy resin cured phase and partially introduce a liquid crystal structure having a high order by self-arrangement during curing thereof (Non Patent Literature 2 to 4).

In addition, it has been described that, when a silsesquioxane compound is used as a matrix, and a nitride filling agent or an oxide filling agent is contained, it is possible to provide an insulating material composition having excellent heat resistance and thermal conductivity (Patent Literature 1). The silsesquioxane compound is a polysiloxane compound in which the main chain framework is composed of Si—O bonds, and which contains a structure unit (hereinafter also simply referred to as a T unit) having 1.5 oxygen atoms for one silicon atom such as [R(SiO)_{3/2}] (R represents an organic group). Patent Literature 1 describes that, since a silsesquioxane compound having a predetermined composition has a siloxane bond moiety and a hydrocarbon group-substituted moiety, the silsesquioxane compound has heat resistance and dielectric strength. In addition, it is described that the silsesquioxane compound has excellent adhesion to boron nitride.

### CITATION LIST

### Patent Literature

Patent Literature 1: Japanese Patent Application Publication No. 2019-133851

### Non-Patent Literature

Non Patent Literature 1: Mimura et al., Highly Thermally Conductive Composite Materials, Network Polymer, Vol. 35, No. 2 (2014), p. 76-82
Non Patent Literature 2: Takezawa et al., Network Polymer, Vol. 31, No. 3 (2010), p. 134-140
Non Patent Literature 3: S-H Song et al., Polymer 53 (2012) 4489-4492
Non Patent Literature 4: Masaki Akatsuka et al., Journal of Applied Polymer Science, Vol. 89, 2464-2467 (2003)
Non Patent Literature 5: Wen-Ying Zhou et al., POLYMER COMPOSITE 2007 23-28

### SUMMARY OF INVENTION

### Technical Problem

However, the epoxy resin as a matrix generally has a problem of performance deterioration due to oxidation and glass transition resulting from heating. In addition, even if a higher-order structure is introduced into the epoxy resin, the resin itself tends to become a solid accordingly, which is not easy to use, and there is a concern of heating and curing conditions being restricted and the higher-order structure collapsing at a high temperature.

In addition, although the silicone resin has excellent heat resistance, the thermal conductivity of the resin itself is low, and high heat dissipation depends on the filler having high thermal conductivity. There is a concern that the silicone resin has adverse effects on electronic components due to decomposition at a high temperature and formation of low-molecular-weight siloxanes.

In addition, for example, the composite of the silsesquioxane compound and boron nitride described in Patent Literature 1 secures heat resistance at 230° C. but the thermal conductivity of about 10 W/m K has been confirmed only at room temperature, and it cannot be said that high thermal conductivity at a high temperature is sufficiently achieved. In addition, considering mounting of an insulation member on a semiconductor element for a power module such as SiC that can operate at a high temperature of about 250° C. to 300° C. using an insulating and highly thermally conductive composite material, further improvement of the thermal conductivity of the resin matrix itself is required.

A silsesquioxane compound is generally known to have heat resistance and dielectric strength. However, the thermal conductivity of silsesquioxane compounds themselves has not been reported or examined.

In view of such circumstances, this specification provides a silsesquioxane derivative that can contribute to further improvement of thermal conductivity. In addition, this specification provides a thermosetting compound containing such a silsesquioxane derivative and an insulating material composition useful as, for instance, an insulating substrate having both high thermal conductivity and an insulating property at a high temperature and a use thereof.

### Solution to Technical Problem

The inventors have focused on a silsesquioxane derivative containing at least T units, and conducted extensive studies. As a result, the inventors have found that, surprisingly, the thermal conductivity of the derivative itself can be improved by increasing the organic content of at least T units. In addition, the inventors have also found that such a silsesquioxane derivative has a better dispersibility and filling ability of a highly thermally conductive filler, and can improve the processability of an insulating material containing a high content of such a filler. Furthermore, the inventors have found that such a silsesquioxane derivative also improves dielectric breakdown properties. Based on these findings, the following aspects are provided.

[1] A silsesquioxane derivative represented by following Formula (1):

[C1]

[SiO_{4/2}]ₛ[R¹—SiO_{3/2}]ₜ[R²—SiO_{3/2}]ᵤ[H—SiO_{3/2}]ᵥ[R³₂—SiO_{2/2}]_{w}[H,R⁴₂—SiO_{1/2}]ₓ[R⁵₃—SiO_{1/2}]_{y} (1)

[in the formula, R¹ is a hydrosilylation-reactive organic group having a carbon-carbon unsaturated bond and having 2 to 30 carbon atoms, R², R³, R⁴ and R⁵ are each independently at least one selected from the group consisting of an alkyl group having 1 to 10 carbon atoms, an aryl group having 5 to 10 carbon atoms and an aralkyl group having 6 to 10 carbon atoms, t, u, w and x are a positive number, and s, v and y are 0 or a positive number].
[2] The silsesquioxane derivative according to [1], wherein, in the Formula (1), u>v.
[3] The silsesquioxane derivative according to [2], wherein, in the Formula (1), 0≤y.
[4] The silsesquioxane derivative according to any one of [1] to [3],

wherein, in the Formula (1),

0<t/(t+u+v+w+x+y)≤0.3,
0<u/(t+u+v+w+x+y)≤0.6,
0<w/(t+u+v+w+x+y)≤0.2, and
0≤y/(t+u+v+w+x+y)≤0.1.
[5] The silsesquioxane derivative according to [4], wherein, in the Formula (1),
0<x/(t+u+v+w+x+y)≤0.3.
[6] The silsesquioxane derivative according to any of [1] to [5], wherein, in the Formula (1), R² and R³ are same.
[7] The silsesquioxane derivative according to any of [1] to [6], wherein, in the Formula (1), R², R³ and R⁴ are same.
[8] The silsesquioxane derivative according to any of [1] to [7], wherein, in the Formula (1), s=0 and v=0, t:u:w:x:y=0.8 or more and 2.2 or less: 1.5 or more and 3.6 or less: 0.25 or more and 0.6 or less: 0.8 or more and 2.2 or less: 0 or more and 0.6 or less.
[9] The silsesquioxane derivative according to any one of [1] to [8], wherein, in the Formula (1), s=0 and v=0, t:u:w:x:y=0.8 or more and 1.2 or less:2.4 or more and 3.6 or less:0.4 or more and 0.6 or less:0.8 or more and 1.2 or less:0 or more and 0.6 or less, R¹ is a vinyl group, and R². R³ and R⁴ are a methyl group (where, when 0<y, R⁵ is a methyl group).
[10] The silsesquioxane derivative according to any of [1] to [9], wherein a molar ratio of C/Si is larger than 0.9.
[11] The silsesquioxane derivative according to any of [1] to [10], wherein a thermal conductivity of a cured product at 25° C. is 0.22 W/mK or more.
[12] A thermosetting composition including the silsesquioxane derivative according to any of [1] to [11].
[13] An adhesive composition including the silsesquioxane derivative according to any of [1] to [11].
[14] A binder composition including the silsesquioxane derivative according to any of [1] to [11].
[15] An insulating material composition including the silsesquioxane derivative according to any of [1] to [11], and a thermally conductive filler.
[16] The insulating material composition according to [15], wherein the thermally conductive filler is a nitride.
[17] The insulating material composition according to [16], wherein the nitride is boron nitride.
[18] The insulating material composition according to [17], wherein the boron nitride has a selective orientation parameter of 0.800 or more and 1.200 or less.
[19] The insulating material composition according to [18], wherein the boron nitride has a selective orientation parameter of 0.850 or more and 1.150 or less.
20] The insulating material composition according to any of [17] to [19], wherein the boron nitride has a crystallite size of 50 nm or more and 300 nm or less.
[21] The insulating material composition according to any of [17] to [20], wherein the boron nitride has a crystallite size of 100 nm or more and 200 nm or less.
[22] The insulating material composition according to [17], wherein the boron nitride has a selective orientation parameter of 0.850 or more and 1.150 or less, and the boron nitride has a crystallite size of 100 nm or more and 200 nm or less.
[23] The insulating material composition according to any of [15] to [22], wherein a content of the thermally conductive filler is 20 vol % or more and 95 vol % or less with respect to a total volume of the silsesquioxane derivative and the thermally conductive filler.
[24] An insulation element including a cured product of the silsesquioxane derivative according to any of [1] to [11], and a thermally conductive filler.
[25] A structure including the insulation element according to [24].
[26] The structure according to [25], which is a semiconductor device.
[27] The structure according to [26], wherein the semiconductor device includes a semiconductor element having a Si layer, a SiC layer or a GaN layer.
[28] A method of producing an insulation element, the method including:

a step of preparing a thermosetting composition containing the silsesquioxane derivative according to any of [1] to [11], and a thermally conductive filler; and

a step of preparing a cured product of the thermosetting composition by curing the silsesquioxane derivative in the thermosetting composition.

[29] A method of producing a structure, the method including:

a step of supplying a cured product of a thermosetting composition containing the silsesquioxane derivative according to any one of [1] to [11] and a thermally conductive filler to an insulation target; and

a step of supplying the thermosetting composition to the insulation target and then supplying the cured product to the insulation target by in-situ curing.

### BRIEF DESCRIPTION OF DRAWINGS

FIG. 1 is a diagram showing analysis results of simultaneous differential thermal weight measurement (TG/DTA) of silsesquioxane derivatives prepared in examples and cured products of comparative examples.

### DESCRIPTION OF EMBODIMENTS

This specification relates to a silsesquioxane derivative effective for increasing thermal conductivity and the like and a use thereof. The silsesquioxane derivative disclosed in this specification (hereinafter referred to as the present silsesquioxane derivative) is a silsesquioxane compound represented by a predetermined composition formula. The present silsesquioxane derivative can exhibit favorable thermal conductivity during curing. Therefore, the present silsesquioxane derivative is useful for insulation elements and structures for which thermal conductivity (heat dissipation effect) is required.

In addition, the present silsesquioxane derivative is a liquid at room temperature (25° C.) and has excellent fluidity, and has favorable dispersion performance and filling performance of a thermally conductive filler. Therefore, it is possible to provide a thermosetting composition having excellent processability even if the thermally conductive filler is contained at a high concentration. In addition, when applied to an insulation target, it is possible to form a structure that sufficiently imitates the unevenness of the insulation target and exhibits an insulating and heat dissipation effect.

In addition, the present silsesquioxane derivative has high heat resistance due to Si—O/Si—C in the structure, and a cured product thereof does not undergo glass transition even at 250° C., and its decomposition is extremely inhibited. Therefore, in the cured product of the present silsesquioxane derivative, for example, even at 200° C. or higher, for example, at 250° C. or higher, and for example, at 300° C. or higher, formation of low-molecular-weight decomposition products at a high temperature, which is a concern for silicone resins and the like, is also inhibited, and thus adverse effects on electronic components such as semiconductor devices are also avoided.

According to the present disclosure, when the cured product of the present silsesquioxane derivative is used as an insulation element such as a heat resistant insulation member of a semiconductor device such as a power module for which a stable operation is required at a high temperature, it can contribute to the provision of a structure, for example, a semiconductor device, having favorable heat dissipation, by exhibiting high heat resistance and excellent thermal conductivity inherent to the cured product of the present silsesquioxane derivative. In addition, according to the present disclosure, since the thermally conductive filler has favorable dispersibility, it has excellent processability for an insulation target and it is possible to contribute to the provision of a structure that is reliably heat-dissipated and insulated. In addition, since the present silsesquioxane derivative can be mixed with many thermally conductive fillers, an effect of improving the thermal conductivity using such a filler can be improved.

In addition, the present silsesquioxane derivative can be easily molded into a form such as a film, a sheet or the like by casting, and may be useful in applying such a 3D-shaped heat dissipation material.

In this specification, the carbon-carbon unsaturated bond is a carbon-carbon double bond or a carbon-carbon triple bond.

In this specification, an article, which is an insulation target, is not particularly limited. Examples thereof include semiconductor devices, computer CPUs, LEDs, and inverters. In addition, examples of structures include semiconductor devices. The semiconductor device is not particularly limited, and examples thereof include a power semiconductor device constituting a so-called power module used for power conversion and power control. Elements and control circuits used in such a power semiconductor device and the like are not particularly limited, and include various known elements and control circuits. In addition, the semiconductor device in this specification includes not only elements and control circuits but also semiconductor modules including units for heat dissipation and cooling.

In addition, the insulation element is a component that is supplied to a location to be insulated and exhibits an insulating function (current cutoff function). Examples of insulation elements include components for which a heat dissipation function and a cooling function are required at the same time. Such insulation elements are not particularly limited, and examples thereof include insulating layers and insulator films in various electronic components and semiconductor devices, as well as insulating films, insulating sheets, and insulating substrates.

In the following, representative, non-limitative, specific embodiments of the present disclosure are described in detail with reference to the attached drawings as needed. The detailed description has been provided for the purpose of merely teaching the details required to carry out preferable embodiments of the present invention to a person skilled in the art, and has not been intended to limit the scope of the present disclosure. The additional characteristics and inventions to be disclosed below can be used independently of or in combination with other characteristics and inventions so as to provide a silsesquioxane derivative having further improvement and use thereof.

The combinations of characteristics and steps to be disclosed in the following detailed description are not essential for carrying out the present disclosure in its broadest reasonable construction but are given for the purpose of merely describing, in particular, the representative, specific examples of the present disclosure. Besides, the various characteristics of the representative, specific examples described above and below and the various characteristics of the matters described in the independent claims and the dependent claims are not necessarily required to be combined in the same way or in the same order as in the specific examples when providing additional and useful embodiments of the present disclosure.

All the characteristics described in the present specification and/or in the claims are disclosed separately and independently of each other for the same purpose as the purpose of the disclosure at the time of filing of the application and for the purpose of restricting the claimed subject matter, independent of the composition of the characteristics described in the embodiments and/or in the claims. In addition, description regarding any numerical range, any group, and any collection are given so as to disclose every possible intermediate value or intermediate entity for the same purpose as the purpose of the disclosure at the time of filing of the application and for the purpose of restricting the claimed subject matter.

Hereinafter, the present silsesquioxane derivative, a method of producing the same, a method of producing a cured product of the present silsesquioxane derivative, and the like will be described in detail.

(Present Silsesquioxane Derivative)

The present silsesquioxane derivative is represented by the following Formula (1).

[C2]

[SiO_{4/2}]ₛ[R¹—SiO_{3/2}]ₜ[R²—SiO_{3/2}]ᵤ[H—SiO_{3/2}]ᵥ[R³₂—SiO_{2/2}]_{w}[H,R⁴₂—SiO_{1/2}]ₓ[R⁵₃—SiO_{1/2}]_{y} (1)

Respective constituent units (a) to (g) that the present silsesquioxane derivative can contain will be referred to as follows and will be described below.

Constituent unit (a): [SiO_{4/2}]ₛ

Constituent unit (b): [R¹—SiO_{3/2}]ₜ
Constituent unit (c): [R²—SiO_{3/2}]ᵤ
Constituent unit (d): [H—SiO_{3/2}]ᵥ
Constituent unit (e): [R³₂—SiO_{2/2}]_{w}
Constituent unit (f): [H, R⁴₂—SiO_{1/2}]ₓ
Constituent unit (g): [R⁵₃—SiO_{1/2}]_{y}

The present silsesquioxane derivative can contain the above constituent units (a) to (g). In Formula (1), s, t, u, v, w, x and y represent a molar ratio of each constituent unit. Here, in Formula (1), s, t, u, v, w, x and y represent a relative molar ratio of each constituent unit contained in the present silsesquioxane derivative represented by Formula (1). That is, the molar ratio is a relative ratio of the number of repetitions of each constituent unit represented by Formula (1). The molar ratio can be determined from an NMR analysis value of the present silsesquioxane derivative. In addition, when the reactivity of each raw material of the present silsesquioxane derivative is clear or the yield is 100%, the molar ratio can be obtained from the amount of the raw materials provided.

For each of the constituent units (b), (c), (e), (f) and (g) in Formula (1), only one type may be used or two or more types may be used. In addition, the sequence in Formula (1) indicates the composition of the constituent unit, and does not mean the sequence thereof. Therefore, the condensed form of the constituent unit in the present silsesquioxane derivative does not necessarily have to be in the sequence of Formula (1).

<Constituent Unit (a): [SiO_{4/2}]ₛ>

The constituent unit (a) is a Q unit including 4 O_{1/2}'s (two oxygen atoms) for one silicon atom. The proportion of the constituent unit (a) in the present silsesquioxane derivative is not particularly limited, but in consideration of the viscosity of the present silsesquioxane derivative, for example, the molar ratio (s/(s+t+u+v+w+x+y)) in all constituent units is 0.1 or less, and is, for example, 0.

<Constituent Unit (b): [R¹—SiO_{3/2}]ₜ>

The constituent unit (b) is a T unit including 3 O_{1/2}'s (1.5 oxygen atoms) for one silicon atom. R¹ may represent a hydrosilylation-reactive organic group having a carbon-carbon unsaturated bond and having 2 to 30 carbon atoms. That is, the organic group R′ may be a hydrosilylation-reactive functional group having a carbon-carbon double bond or a carbon-carbon triple bond. Specific examples of such an organic group R¹ are not particularly limited, and examples thereof include a vinyl group, orthostyryl group, metastyryl group, parastyryl group, acryloyloxy methyl group, methacryloyloxy methyl group, 2-acryloyloxymethyl group, 2-methacryloyloxemethyl group, 3-acryloyloxypropyl group, 3-methacryloyloxypropyl group, 1-propenyl group, 2-propenyl group, 1-methylethenyl group, 1-butenyl group, 3-butenyl group, 1-pentenyl group, 4-pentenyl group, 3-methyl-1-butenyl group, 1-phenylethenyl group, 2-phenylethenyl group, ethynyl group, 1-propynyl group, 2-propynyl group, 1-butynyl group, 3-butynyl group, 1-pentynyl group, 4-pentynyl group, 3-methyl-1-butynyl group, and phenylbutynyl group.

The silsesquioxane derivative represented by Formula (1) can contain two or more types of organic groups R′ as a whole, and in this case, all organic groups R¹ may be the same as or different from each other. The organic group R′ is, for example, a vinyl group having a small number of carbon atoms or a 2-propenyl group (allyl group) so that a raw material monomer forming the constituent unit (1-2) can be easily obtained. Here, the inorganic moiety indicates a SiO moiety.

In addition, in the constituent unit (b). R¹ can include at least one selected from among an alkylene group having 1 to 20 carbon atoms (divalent aliphatic group), a divalent aromatic group having 6 to 20 carbon atoms and a divalent alicyclic group having 3 to 20 carbon atoms as exemplified above. Examples of alkylene groups having 1 to 20 carbon atoms include a methylene group, ethylene group, n-propylene group, i-propylene group, n-butylene group, and i-butylene group. Examples of divalent aromatic groups having 6 to 20 carbon atoms include a phenylene group and naphthylene group. In addition, examples of divalent alicyclic groups having 3 to 20 carbon atoms include divalent hydrocarbon groups having a norbornene framework, a tricyclodecane framework or an adamantane framework.

R¹ is an organic group having 2 to 30 carbon atoms, and if the number of carbon atoms is small, the proportion of inorganic moieties of the cured product of the present silsesquioxane derivative can increase and the heat resistance can improve so that the number of carbon atoms is preferably 2 to 20, the number of carbon atoms is more preferably 2 to 10, and the number of carbon atoms is still more preferably 2 to 5. For example, a vinyl group having a small number of carbon atoms and a 2-propenyl group (allyl group) are particularly preferable.

<Constituent Unit (c): [R²—SiO_{3/2}]ᵤ>

The constituent unit (c) is a T unit including 3 O_{1/2}'s for one silicon atom. R² can be at least one selected from the group consisting of an alkyl group having 1 to 10 carbon atoms, an aryl group having 5 to 10 carbon atoms and an aralkyl group having 6 to 10 carbon atoms. The constituent unit (c) is different from the constituent unit (d) described below in that it does not include hydrogen atoms. The constituent unit (c) contributes to improvement of the thermal conductivity of the present silsesquioxane derivative. In addition, it is possible to reduce the amount of hydrogen atoms remaining in the cured product of the present silsesquioxane derivative. In addition, it can contribute to the increase in the molar ratio of C/Si of the present silsesquioxane derivative. In addition, the hydrosilylation reaction in the present silsesquioxane derivative can be regulated between the constituent unit (a) and the constituent unit (f), and the structural regularity can be improved, which can contribute to improvement of the thermal conductivity in some cases.

The alkyl group having 1 to 10 carbon atoms may be either an aliphatic group or an alicyclic group, and may be linear or branched. Although not particularly limited, for example, a methyl group, ethyl group, propyl group, butyl group, pentyl group, hexyl group, heptyl group, octyl group, nonyl group, decyl group and the like may be exemplified. In consideration of the thermal conductivity, for example, a methyl group, and ethyl group may be exemplified. In addition, for example, a methyl group is used.

The aryl group having 5 to 10 carbon atoms is not particularly limited, and for example, a phenyl group and a phenyl group substituted with an alkyl group having 1 to 4 carbon atoms may be exemplified. In consideration of the thermal conductivity, for example, a phenyl group may be exemplified.

The aralkyl group having 6 to 10 carbon atoms is not particularly limited, and examples thereof include an alkyl group in which one hydrogen atom of an alkyl group having 1 to 4 carbon atoms is substituted with an aryl group such as a phenyl group. For example, a benzyl group and a phenethyl group may be exemplified.

When R² contained in the constituent unit (c) is an alkyl group having 1 to 4 carbon atoms such as a methyl group, a plurality of R³'s in the constituent unit (e) described below can be the same. Accordingly, the thermal conductivity and the filler dispersibility can be improved. In addition, when R² is an aryl group such as a phenyl group, a phenyl group or an aralkyl group such as a phenyl group, a plurality of R³'s in the constituent unit (e) (D unit) described below can be the same. Accordingly, the thermal conductivity and the filler dispersibility can be improved. In addition, when R² is an alkyl group having 1 to 4 carbon atoms such as a methyl group, it can be the same as R⁴ in the constituent unit (f). In addition, similarly, it can be the same as R⁵ in the constituent unit (g). R² is more preferably a methyl group or a phenyl group because it has good balance of the heat resistance, dispersibility and viscosity.

<Constituent Unit (d): [H—SiO_{3/2}]ᵥ>

Like the constituent unit (c), the constituent unit (d) is also a T unit including 3 O_{1/2}'s for one silicon atom, but the constituent unit (d) is different from the constituent unit (c), and includes a hydrogen atom that binds to a silicon atom. The proportion of the constituent unit (d) in the present silsesquioxane derivative is not particularly limited, but in consideration of the thermal conductivity and heat resistance of the present silsesquioxane derivative, for example, the molar ratio in all constituent units is 0.1 or less, and is, for example, 0.

<Constituent Unit (e): [R³₂—SiO_{2/2}]_{w}>

The constituent unit (e) is a D unit including 2 O_{1/2}'s (one oxygen atom) for one silicon atom. R³ may represent at least one selected from the group consisting of an alkyl group having 1 to 10 carbon atoms, an aryl group having 5 to 10 carbon atoms and an aralkyl group having 6 to 10 carbon atoms. A plurality of R³'s contained in the constituent unit (e) may be the same as or different from each other. These substituents include various forms defined for R³ of the constituent unit (c).

<Constituent Unit (f): [H, R⁴₂—SiO_{1/2}]ₓ>

The constituent unit (f) is a unit including one O_{1/2} (0.5 oxygen atom) for one silicon atom. R⁴ may represent at least one selected from the group consisting of an alkyl group having 1 to 10 carbon atoms, an aryl group having 5 to 10 carbon atoms and an aralkyl group having 6 to 10 carbon atoms. A plurality of R⁴'s contained in the constituent unit (f) may be the same as or different from each other. These substituents include various forms defined for R² of the constituent unit (c).

<Constituent Unit (g): [R⁵₃—SiO_{1/2}]_{y}>

The constituent unit (g) is an M unit including one O_{1/2} (0.5 oxygen atom) for one silicon atom. The constituent unit (g) is different from the constituent unit (f) in that it does not include a hydrogen atom bonded to a silicon atom, and all are an alkyl group or the like. With this constituent unit, the organic content of the present silsesquioxane derivative can be improved, and the viscosity can also be lowered. R⁵ may represent at least one selected from the group consisting of an alkyl group having 1 to 10 carbon atoms, an aryl group having 5 to 10 carbon atoms and an aralkyl group having 6 to 10 carbon atoms. A plurality of R⁵'s contained in the constituent unit (g) may be the same as or different from each other. These substituents include various forms defined for R² of the constituent unit (c).

The present silsesquioxane derivative can further include [R⁶O_{1/2}] as a constituent unit containing no Si. Here, R⁶ is a hydrogen atom or an alkyl group having 1 to 6 carbon atoms, and may be either an aliphatic group or an alicyclic group, and may be linear or branched. Specific examples of alkyl groups include a methyl group, ethyl group, propyl group, butyl group, pentyl group, and hexyl group.

This constituent unit is a hydroxy group which is an alkoxy group which is a hydrolyzable group contained in a raw material monomer to be described below or an alkoxy group generated by substituting a hydrolyzable group of a raw material monomer with an alcohol contained in a reaction solvent, which remains in the molecule without hydrolysis/polycondensation or remains in the molecule without polycondensation after hydrolysis.

As described above, the constituent units of the present silsesquioxane derivative each can independently have various forms, and for example, a vinyl group, an allyl group or the like is preferable as R¹. In addition, for example, in the constituent unit (c), the constituent unit (e), the constituent unit (f) and the constituent unit (g), preferably, R², R³, R⁴ and R⁵ each independently are an alkyl group having 1 to 10 carbon atoms such as a methyl group, more preferably. R² and R³ are the same alkyl group such as a methyl group, still more preferably, R², R³ and R⁴ are the same alkyl group such as a methyl group, and yet more preferably. R², R³, R⁴ and R⁵ (where, 0<y) are the same alkyl group such as a methyl group. In addition, for example, in the constituent unit (c) and the constituent unit (e), R² and R³ are an aryl group such as a phenyl group, and the constituent unit (f) and the constituent unit (g) are preferably an alkyl group such as a methyl group.

In the molar ratio of each constituent unit, t, u, w and x are a positive number, and s, v and y are 0 or a positive number. Here, a molar ratio of 0 indicates that the constituent unit is not included.

The proportion of the constituent unit (a) in the present silsesquioxane derivative is not particularly limited, but in consideration of the viscosity of the present silsesquioxane derivative, the molar ratio (s/(s+t+u+v+w+x+y)) in all constituent units of Formula (1) is, for example, 0.1 or less, and is, for example, 0.

The proportion of the constituent unit (b) in the present silsesquioxane derivative is not particularly limited, but in consideration of the curability and the like of the present silsesquioxane derivative, the molar ratio (t/(s+t+u+v+w+x+y)) in all constituent units of Formula (1) is, for example, more than 0 and 0.3 or less. When the constituent unit (b) which is a T unit having crosslink reactivity is provided at such a molar ratio, it is possible to obtain a silsesquioxane derivative having a favorable cross-linked structure. In addition, for example, the molar ratio is 0.1 or more, and for example, 0.15 or more, and for example, 0.17 or more, and for example, 0.18 or more, and for example, 0.20 or more, and for example, 0.25 or more. In addition, for example, 0.28 or less, and for example, 0.27 or less, and for example, 0.26 or less. These lower limits and upper limits can be combined, and are, for example, 0.1 or more and 0.27 or less, and for example, 0.15 or more and 0.26 or less.

The proportion of the constituent unit (c) in the present silsesquioxane derivative is not particularly limited, but in consideration of the thermal conductivity and the like of the present silsesquioxane derivative, the molar ratio (u/(s+t+u+v+w+x+y)) in all constituent units of Formula (1) is, for example, more than 0 and 0.6 or less. In addition, for example, 0.2 or more, and for example, 0.3 or more, and for example, 0.35 or more, and for example, 0.4 or more, and for example, 0.45 or more, and for example, 0.5 or more, and for example, 0.55 or more. In addition, for example, 0.55 or less, and for example, 0.5 or less, and for example, 0.4 or less. These lower limits and upper limits can be combined, and are, for example, 0.3 or more and 0.6 or less, and for example, 0.4 or more and 0.55 or less.

The proportion of the constituent unit (d) in the present silsesquioxane derivative is not particularly limited, but in consideration of the thermal conductivity and the heat resistance of the present silsesquioxane derivative, the molar ratio (v/(s+t+u+v+w+x+y)) in all constituent units of Formula (1) is, for example, 0.1 or less, and for example, 0.05 or less, and for example, 0.

In Formula (1), for example, u>v. That is, it means that, regarding the constituent unit (c) and the constituent unit (d), which are both the T unit, the number of constituent units (c) is larger than that of the constituent units (d). Preferably, u/(u+v) is, for example, 0.6 or more, and for example, 0.7 or more, and for example, 0.8 or more, and for example, 0.9 or more, and for example, 1.

The proportion of the constituent unit (e) in the present silsesquioxane derivative is not particularly limited, but in consideration of the viscosity and the like of the present silsesquioxane derivative, the molar ratio (w/(s+t+u+v+w+x+y)) in all constituent units of Formula (1) is, for example, more than 0 and 0.2 or less. In addition, for example, 0.05 or more, and for example, 0.07 or more, and for example, 0.08 or more, and for example, 0.09 or more, and for example, 0.1 or more. In addition, for example, 0.18 or less, and for example, 0.16 or less, and for example, 0.15 or less. These lower limits and upper limits can be combined, and are for example, 0.04 or more and 0.15 or less, and for example, 0.05 or more and 0.1 or less.

The proportion of the constituent unit (0 in the present silsesquioxane derivative is not particularly limited, but in consideration of the heat resistance, the viscosity, the curability and the like of the present silsesquioxane derivative, the molar ratio (x/(s+t+u+v+w+x+y)) in all constituent units of Formula (1) is, for example, more than 0 and 0.3 or less. In addition, for example, the molar ratio is 0.1 or more, and for example, 0.15 or more, and for example, 0.17 or more, and for example, 0.18 or more, and for example, 0.20 or more, and for example, 0.25 or more. In addition, for example, 0.28 or less, and for example, 0.27 or less, and for example, 0.26 or less. These lower limits and upper limits can be combined, and are for example, 0.1 or more and 0.27 or less, and for example, 0.15 or more and 0.26 or less.

The proportion of the constituent unit (g) in the present silsesquioxane derivative is not particularly limited, but in consideration of the viscosity and the like of the present silsesquioxane derivative, the molar ratio (y/(s+t+u+v+w+x+y)) in all constituent units is, for example, 0 or more and 0.1 or less, and for example, 0 or more and 0.08 or less, and for example, 0 or more and 0.05 or less, and for example, 0.

In addition, in Formula (1), in consideration of the curability and heat resistance, x>y. This is because, when the constituent unit (0, which is an M unit, is provided, it is possible to contribute to the decrease in the viscosity of the present silsesquioxane, but if the amount of the constituent unit (g), which is another M unit, is large, there is a risk of the curability and heat resistance decreasing. x/(x+y) is, for example, 0.5 or more, and for example, 0.7 or more, and for example, 0.8 or more, and for example, 0.9 or more, and for example, 1.

In the present silsesquioxane derivative, the molar ratio of each constituent unit in Formula (1) can satisfy the following condition (1) or (2). When such a molar ratio is satisfied, it is possible to obtain a silsesquioxane derivative having a good balance of the thermal conductivity, heat resistance and viscosity. Here, in the following molar ratio, preferably, t=1.

(1) s=0 and v=0, t:u:w:x:y=0.8 or more and 2.2 (preferably, 1.2 or less) or less:1.5 or more and 3.6 or less:0.25 or more and 0.6 or less:0.8 or more and 2.2 (preferably, 1.2) or less:0 or more and 0.6 or less
(2) s=0 and v=0, t:u:w:x:y=0.8 or more and 1.2 or less:2.4 or more and 3.6 or less:0.4 or more and 0.6 or less:0.8 or more and 1.2 or less:0 or more and 0.6 or less, A is a vinyl group, and R², R³ and R⁴ are a methyl group (where, 0<y, R⁵ is a methyl group).

In the present silsesquioxane derivative, the molar ratio of C/Si is, for example, more than 0.9. This is because the thermal conductivity is improved in such a range. In addition, for example, the molar ratio is 1 or more, and for example, 1.2 or more. The molar ratio of C/Si can be obtained by evaluating the present silsesquioxane derivative by, for example, ¹H-NMR measurement. Since signals with a chemical shill δ(ppm) of −0.2 to 0.6 are considered to be based on a structure of Si—CH₃. signals with a δ(ppm) of 0.8 to 1.5 are considered to be based on structures of OCH(CH₃)CH₂CH₃, OCH(CH₃)₂ and OCH₂CH₃, signals with a δ(ppm) of 3.5 to 3.9 are considered to be based on a structure of OCH₂CH₃, signals with a δ(ppm) of 3.9 to 4.1 are considered to be based on a structure of OCH(CH₃)CH₂CH₃, signals with a δ(ppm) of 4.2 to 5.2 are considered to be based on a structure of Si—H, and signals with a δ(ppm) of 5.7 to 6.3 are considered to be based on a structure of CH═CH₂, from each signal intensity integrated value, simultaneous equations for side chains can be established and determined. Here, regarding the constituent unit T, it is known that the prepared monomer s (triethoxysilane, trimethoxyvinylsilane, etc.) are directly incorporated into the silsesquioxane derivative, and thus the molar ratio of each constituent unit contained in the silsesquioxane derivative can be determined from the value of all monomers prepared and the NMR measured value, and additionally, the molar ratio of C/Si can be determined.

<Molecular Weight. Etc.>

The number average molecular weight of the present silsesquioxane derivative is preferably in a range of 300 to 30,000. Such a silsesquioxane is a liquid in itself, has a low viscosity suitable for handling, is easily dissolved in an organic solvent, is easy to handle the viscosity of the solution, and has excellent storage stability. The number average molecular weight is more preferably 500 to 15,000, still more preferably 700 to 10,000, and particularly preferably 1,000 to 5,000. For example, the number average molecular weight can be determined through gel permeation chromatography (GPC) using polystyrene as a standard substance under measurement conditions in [Examples] to be described below.

The present silsesquioxane derivative is a liquid, and the viscosity at 25° C. is preferably 100,000 mPa·s or less, more preferably 80,000 mPa·s or less, and particularly preferably 50,000 mPa·s or less. However, the lower limit of the viscosity is generally 1 mPa·s. Here, the viscosity can be measured at 25° C. using an E type viscometer (TVE22H type viscometer commercially available from Toki Sangyo Co., Ltd.).

<Method for Producing Present Silsesquioxane Derivative>

The present silsesquioxane derivative can be produced using a publicly known method. Methods for producing the present silsesquioxane derivative are disclosed in detail as methods for producing polysiloxanes disclosed in the pamphlets of WO 2005/01007, WO 2009/066608 and WO 2013/099909. Japanese Patent Application Publication Nos. 2011-052170 and 2013-147659, and the like.

The present silsesquioxane derivative can be produced using, for example, the following method. That is, the method for producing the present silsesquioxane derivative can include a condensation step in which raw material monomers that give constituent units in formula (1) above are subjected to a hydrolysis/polycondensation reaction through condensation in an appropriate reaction solvent. For example, a silicon compound having four siloxane bond-forming groups (hereinafter referred to as a “Q monomer”) that forms constituent unit (a) (Q unit), a silicon compound having three siloxane bond-forming groups (hereinafter referred to as a “T monomer”) that forms constituent unit (b)-(d) (T unit), a silicon compound having two siloxane bond-forming groups (hereinafter referred to as a “D monomer”) that forms constituent unit (e) (D unit) and a silicon compound having one siloxane bond-forming group (hereinafter referred to as an “M monomer”) that forms constituent unit (0 and (g) (M unit) can be used in this condensation step.

In this specification, for example, at least one type is used for each of the T monomer forming the constituent unit (b), the T monomer forming the constituent units (c) and (d), the D monomer forming the constituent unit (e), and the M monomer forming the constituent units (f) and (g). It is preferable to provide a distillation process in which raw material monomers are subjected to a hydrolysis/polycondensation reaction in the presence of a reaction solvent and the reaction solvent by-products, residual monomers, water and the like in the reaction solution are then distilled off.

Siloxane bond-forming groups contained in the Q monomer, T monomer, D monomer and M monomer that are raw material monomers are hydroxyl groups or hydrolyzable groups. Of these, halogeno groups and alkoxy groups can be given as examples of hydrolyzable groups. It is preferable for at least one of the Q monomer, T monomer, D monomer and M monomer to have a hydrolyzable group. In the condensation step, an alkoxy group is preferred as the hydrolyzable group, and an alkoxy group having 1 to 3 carbon atoms is more preferred, from the perspectives of exhibiting good hydrolysis properties and not causing an acid to be by-produced.

In the condensation step, it is preferable for siloxane bond-forming groups in the Q monomer, T monomer or D monomer that correspond to the respective constituent units to be alkoxy groups, and for a siloxane bond-forming group contained in the M monomer to be an alkoxy group or a siloxy group. In addition, a monomer that corresponds to a constituent unit may be a single monomer or a combination of two or more types thereof.

Examples of Q monomers that form the constituent unit (a) include tetramethoxysilane, tetraethoxysilane, tetrapropoxysilane, and tetrabutoxysilane. Examples of T monomers that form the constituent unit (b) include trimethoxyvinylsilane, triethoxyvinylsilane, (p-styryl)trimethoxysilane, (p-styryl)triethoxysilane, (3-methacryloyloxypropyl)trimethoxysilane, (3-methacryloyloxypropyl)triethoxysilane, (3-acryloyloxypropyl)trimethoxysilane, and (3-acryloyloxypropyl)triethoxysilane. Examples of T monomers that form the constituent unit (c) include methyltrimethoxysilane, methyltriethoxysilane, methyltripropoxysilane, methyltriisopropoxysilane, ethyltrimethoxysilane, ethyl triethoxysilane, propyltriethoxysilane, butyltrimethoxysilane, cyclohexyltrimethoxysilane, and cyclohexyltriethoxysilane. Examples of T monomers that form the constituent unit (d) include trimethoxysilane, triethoxysilane, tripropoxysilane, and trichlorosilane. Examples of D monomers that form the constituent unit (e) include dimethoxydimethylsilane, dimethoxydiethylsilane, diethoxydimethylsilane, diethoxydiethylsilane, dipropoxydimethylsilane, dipropoxydiethylsilane, dimethoxybenzylmethylsilane, diethoxybenzylmethylsilane, dichlorodimethylsilane, dimethoxymethylsilane, dimethoxymethylvinylsilane, diethoxymethylsilane, and diethoxymethylvinylsilane. Examples of M monomers that give constituent unit (f) (g) include hexamethyldisiloxane, hexaethyldisiloxane, hexapropyldisiloxane, 1,1,3,3-tetramethyldisiloxane, 1,3-divinyl-1,1,3,3-tetramethyldisiloxane, methoxydimethylsilane, ethoxydimethylsilane, methoxydimethylvinylsilane and ethoxydimethylvinylsilane, which gave two constituent units (f) through hydrolysis, and moreover methoxytrimethylsilane, ethoxytrimethylsilane, methoxydimethylphenylsilane, ethoxydimethylphenylsilane, chlorodimethylsilane, chlorodimethylvinylsilane, chlorotrimethylsilane, dimethylsilanol, dimethylvinylsilanol, trimethylsilanol, triethylsilanol, tripropylsilanol and tributylsilanol. Examples of organic compounds that form the constituent unit (h) include alcohols such as 2-propanol, 2-butanol, methanol, and ethanol.

An alcohol can be used as a reaction solvent in the condensation step. Strictly speaking, the alcohol is a compound which is represented by the general formula R—OH and does not contain functional groups other than an alcoholic hydroxyl group. Although not particularly limited, examples thereof include methanol, ethanol, n-propyl alcohol, isopropyl alcohol, 2-butanol, 2-pentanol, 3-pentanol, 2-methyl-2-butanol, 3-methyl-2-butanol, cyclopentanol, 2-hexanol, 3-hexanol, 2-methyl-2-pentanol, 3-methyl-2-pentanol, 2-methyl-3-pentanol, 3-methyl-3-pentanol, 2-ethyl-2-butanol, 2,3-dimethyl-2-butanol and cyclohexanol. Of these, secondary alcohols such as isopropyl alcohol, 2-butanol, 2-pentanol, 3-pentanol, 3-methyl-2-butanol, cyclopentanol, 2-hexanol. 3-hexanol, 3-methyl-2-pentanol and cyclohexanol can be used. In the condensation step, it is possible to use one of these alcohols or a combination of two or more types thereof. More preferred alcohols are compounds that can dissolve a required concentration of water in the condensation step. Alcohols having such a property are compounds in which the solubility of water is 10 g or more per 100 g of alcohol at 20° C.

By using an alcohol in the condensation step at a quantity of 0.5 mass % or more relative to the total amount of reaction solvent, including additionally introduced components during the hydrolysis/polycondensation reaction, it is possible to suppress gelling of the present silsesquioxane derivative being produced. A preferred usage amount is 1 mass % to 60 mass %, and more preferably 3 mass % to 40 mass %.

The reaction solvent used in the condensation step may be an alcohol in isolation, or a mixed solvent that further contains at least one type of secondary solvent. A secondary solvent may be a polar solvent, a non-polar solvent or a combination of both of these types. A preferred polar solvent is a secondary or tertiary alcohol having 3 or 7 to 10 carbon atoms, a diol having 2 to 20 carbon atoms, or the like.

The non-polar solvent is not particularly limited, but examples thereof include aliphatic hydrocarbons, alicyclic hydrocarbons, aromatic hydrocarbons, chlorinated hydrocarbons, ethers, amides, ketones, esters and cellosolve solvents. Of these, aliphatic \hydrocarbons, alicyclic hydrocarbons and aromatic hydrocarbons are preferred. Such non-polar solvents are not particularly limited, but, for example, n-hexane, isohexane, cyclohexane, heptane, toluene, xylene, methylene chloride, and the like, are preferred due to being azeotropic with water, and by additionally using these compounds, it is possible to efficiently distill off moisture when removing the reaction solvent by distillation from the reaction mixture containing the present silsesquioxane derivative after the condensation step. Xylene, which is an aromatic hydrocarbon, is particularly preferred as the non-polar solvent due to having a relatively high boiling point.

The hydrolysis/polycondensation reaction in the condensation process proceeds in the presence of water. The amount (mol) of water used to hydrolyze hydrolyzable groups contained in the raw material monomers is preferably 0.5 to 5 times, and more preferably 1 to 2 times the amount of hydrolyzable groups. In addition, the hydrolysis/polycondensation reaction of raw material monomers may be performed in the absence of a catalyst or may be performed using a catalyst. When a catalyst is used, generally, an acid catalyst exemplified as an inorganic acid such as sulfuric acid, nitric acid, hydrochloric acid, and phosphoric acid; and an organic acid such as formic acid, acetic acid, oxalic acid, and p-toluenesulfonic acid is preferably used. The usage quantity of the acid catalyst is preferably an amount corresponding to 0.01 mol % to 20 mol %, and more preferably an amount corresponding to 0.1 mol % to 10 mol %, relative to the total amount of silicon atoms contained in the raw material monomers.

Completion of the hydrolysis/polycondensation reaction in the condensation step can be detected as appropriate using methods disclosed in the publications mentioned above. Moreover, it is possible to add auxiliary agents to the reaction system in the condensation step for producing the present silsesquioxane derivative. Examples of auxiliary agents include anti-foaming agents for suppressing foaming of the reaction liquid, scale control agents for preventing scale from adhering to a reactor or stirring shaft, polymerization inhibitors and hydrosilylation reaction inhibitors. Usage quantities of these auxiliary agents are discretionary, but are preferably 1 mass % to 100 mass % relative to the concentration of the present silsesquioxane derivative in the reaction mixture.

When a distillation process in which the reaction solvent and by-products contained in the reaction solution obtained in the condensation process, residual monomers, water and the like are distilled off is provided after the condensation process in the production of the present silsesquioxane derivative, the stability of the produced present silsesquioxane derivative can be improved.

(Thermosetting Composition)

The thermosetting composition disclosed in this specification (hereinafter referred to as the present composition) contains the present silsesquioxane derivative. The present silsesquioxane derivative has excellent fluidity and dispersibility of the thermally conductive filler and as will be described below, it has excellent thermal conductivity and heat resistance of the cured product, and is therefore a favorable insulating material for an insulation element for which heat dissipation is required. In addition, since the present composition itself can exhibit favorable curability and adhesiveness, it can be used as an adhesive composition or a filler binder composition.

The present composition may contain a thermally conductive filler in addition to the present silsesquioxane derivative. The present silsesquioxane derivative functions as a favorable binder for a thermally conductive filler and also functions as a high thermal conductivity matrix that can effectively impart high thermal conductivity to the cured product obtained by curing this composition. Therefore, the present composition is useful as an insulating material composition for forming various insulation elements.

The thermally conductive filler is not particularly limited, and examples of non-conductive fillers include alumina, boron nitride, aluminum nitride, silicon carbide, silicon nitride, silica, aluminum hydroxide, barium sulfate, magnesium oxide, and zinc oxide. In addition, examples of conductive fillers include graphite, gold, silver, nickel, and copper. One type or two or more types of thermally conductive fillers can be used depending on applications and the like of the present composition.

As the thermally conductive filler, nitride ceramics such as boron nitride, aluminum nitride and silicon nitride can be preferably used. It has excellent dispersibility and adhesion with respect to the silsesquioxane derivative and can effectively improve the thermal conductivity in combination with high thermal conductivity of the present silsesquioxane derivative.

The particle size such as the average particle size and the median diameter of the thermally conductive filler is not particularly limited, and for example, the median diameter or the average particle size may be 1 μm or more and 1,000 μm or less, and for example, 10 μm or more and 200 μm or less. Here, the particle size such as the average particle size and the median diameter can be measured by a laser diffraction scattering method. Specifically, a particle size distribution of the thermally conductive filler is created based on the volume using a laser diffraction scattering type particle size distribution measuring device, and the average particle size and the median diameter thereof can be measured. Here, when thermally conductive fillers are secondary particles which are an aggregate of primary particles, the average particle size, the median diameter and the like of the secondary particles correspond to the average particle size, the median diameter and the like of the thermally conductive fillers.

The shape of the thermally conductive filler is not particularly limited, and examples thereof include a spherical shape, a rod shape, a needle shape, a columnar shape, a fibrous shape, a plate shape, a scaly shape, a nanosheet and a nanofiber, and the shape may be crystalline or amorphous. Here, when the thermally conductive fillers are secondary particles which are an aggregate of primary particles, the shape of the secondary particles corresponds to the shape of the thermally conductive fillers.

The thermally conductive filler such as boron nitride may have a median diameter that is, for example, 5 μm or more and 200 μm or less, and for example, 10 μm or more and 200 μm or less, and for example, 10 μm or more and 180 μm or less, and for example, 20 μm or more and 150 μm or less, and for example, 30 μm or more and 180 μm or less, and for example, 50 μm or more and 150 μm or less. In addition, the median diameter may be, for example, 20 μm or more and 100 μm or less, and for example, 30 μm or more and 100 μm or less, and for example, 40 μm or more and 100 μm or less. In the present silsesquioxane derivative, when the median diameter of the thermally conductive filler used is selected, it is possible to improve the thermal conductivity of the cured product and secure an insulating property at a high temperature. Particularly, for example, when the median diameter of the thermally conductive filler is 20 μm or more, the combination with the present silsesquioxane derivative can contribute to improvement of the thermal conductivity. In addition, for example, the median diameter is 30 μm or more, and for example, 40 μm or more. In addition, even if the median diameter or the average particle size is 100 μm or less or 90 μm or less, the combination with the present silsesquioxane derivative can contribute to improvement of the thermal conductivity.

The thermally conductive filler such as boron nitride may have a crystallite size that is, for example, 50 nm or more, and for example, 60 nm or more, and for example, 70 nm or more, and for example, 80 nm or more, and for example, 90 nm or more, and for example, 100 nm or more, and for example, 110 nm or more, and for example, 120 nm or more, and for example, 130 nm or more, and for example, 140 nm or more, and for example, 150 nm or more. A larger crystallite size can contribute to the increase in thermal conductivity. In addition, the crystallite size may be, for example, 300 nm or less, and for example, 280 nm or less, and for example, 260 nm or less, and for example, 240 nm or less, and for example, 220 nm or less, and for example, 200 nm or less, and for example, 190 nm or less, and for example, 180 nm or less, and for example, 170 nm or less and for example, 180 nm or less. A larger crystallite size can contribute to the increase in thermal conductivity. This is because a large crystallite size can contribute to the increase in thermal conductivity, but it has an effect on the practical point of view and the median diameter and the like of the thermally conductive filler. The range of crystallite size can be set by combining any of these lower limit values and upper limit values, and may be, for example, 50 nm or more and 300 nm or less, and for example, 50 nm or more and 200 nm or less, and for example, 80 nm or more and 200 nm or less, and for example, 100 nm or more and 200 nm or less, and for example, 100 nm or more and 190 nm or less, and for example, 110 nm or more and 190 nm or less. In the present silsesquioxane derivative, when the crystallite size of the thermally conductive filler used is selected, it is possible to improve the thermal conductivity of the cured product. Here, the crystallite size of the thermally conductive filler can be measured by a method (X-ray diffraction method) disclosed in examples.

For the thermally conductive filler such as boron nitride, the selective orientation parameter in the selective orientation function may be, for example, 0.700 or more and 1.300 or less, and for example, 0.800 or more and 1.200 or less, and for example, 0.850 or more and 1.150 or less, and for example, 0.900 or more and 1.100 or less, and for example 0.970 or more and 1.030 or less, and for example, 0.975 or more and 1.025 or less, and for example, 0.980 or more and 1.020 or less, and for example, 0.985 or more and 1.015 or less, and for example, 0.990 or more and 1.010 or less, 0.995 or more and 1.005 or less. In the present silsesquioxane derivative, the thermal conductivity of the cured product can be improved by selecting a value closer to 1.000 for the selective orientation parameter of the thermally conductive filler used. Here, when the selective orientation parameter is 1, it means that there is no orientation, and a parameter closer to 1 indicates a smaller orientation.

The selective orientation parameter is a value related to the selective orientation function, and is a value that is an index of the orientation state. The selective orientation parameter is described in the literature (W. A. Dollase, J. Appl. Crystallogr., 19, 267 (1986)). The selective orientation parameter is defined by performing a powder X-ray diffraction simulation. A peak intensity ratio (I₁/I₂) of the (002) plane and (100) plane when the selective orientation parameter (r value) changes from 0.5 to 5 is obtained, and the relationship between the r value and I₁/I₂ is approximated to a power expression by the least squares method. Here, when the r value is about 1, the state is a non-orientated state, and it can be said that, when the r value is large based on the non-orientated state, the a plane (that is, the (100) plane) orientation is strong, and when the r value is small, the c plane (that is, the (001) plane) orientation is strong. The selective orientation parameter is calculated by performing a simulation using general Rietveld analysis software for powder x-ray diffraction. The selective orientation parameter in this specification is specifically defined by a method disclose in examples.

When the particle size such as the median diameter, the crystallite size and the selective orientation parameter are appropriately combined, the thermally conductive filler such as boron nitride can improve the thermal conductivity of the cured product by an additive and/or synergistic effect in combination with the present silsesquioxane derivative.

When the present composition contains the present silsesquioxane derivative and a thermally conductive filler, although not particularly limited, with respect to a total volume of these, the content of the thermally conductive filler is 20 vol % or more and 95 vol % or less, and for example 30 vol % or more and 85 vol % or less, and for example 40 vol % or more and 80 vol % or less. Based on the inorganic-organic hybrid composition, the present silsesquioxane derivative has excellent dispersibility of the thermally conductive filler such as a ceramic, and even if the thermally conductive filler is contained in a high concentration, it is possible to prepare the present composition having excellent processability and fluidity. In particular, the dispersibility and filling ability of boron nitride are better than those of conventional silsesquioxane compounds, and even with a filler such as scaly boron nitride which has problems in the dispersibility and filling ability, it is possible to obtain a cured product having an improved filling ability.

The present composition can contain other components, as necessary, in addition to the present silsesquioxane derivative and the thermally conductive filler. For example, resin components other than the silsesquioxane compound, and additives such as an antioxidant, a flame retardant, and a colorant may be exemplified.

In addition, the present curable composition can contain, as necessary, a solvent, a catalyst and the like for the present silsesquioxane derivative to be described below. Here, the solvent and the catalyst can be added in production of the cured product to be described below.

When a heat treatment is performed to the present composition by a method of curing the present silsesquioxane derivative described below, the present silsesquioxane derivative can be cured to obtain a cured product containing a thermally conductive filler.

<Cured Product of Present Silsesquioxane Derivative and Method of Curing Silsesquioxane Derivative>

In the silsesquioxane derivative, according to a hydrolysis/polycondensation of alkoxysilyl groups in the present silsesquioxane derivative and/or a hydrosilylation reaction between hydrosilyl groups in the silsesquioxane derivative and hydrosilylation-reactive carbon-carbon unsaturated groups, a cured product (hereinafter referred to as the present cured product) of the silsesquioxane derivative having a cross-linked structure can be obtained. The present cured product may be produced in the absence of a catalyst, or a catalyst for a hydrosilylation reaction may be used. A catalyst that can be used for curing will be described below in detail.

For the present silsesquioxane derivative, the curing reaction is not particularly limited, and for example, generally, according to a heat treatment, a cured product having a cross-linked structure can be obtained by a hydrolysis/polycondensation of alkoxysilyl groups and/or a hydrosilylation reaction between hydrosilyl groups and hydrosilylation-reactivecarbon-carbon unsaturated groups. When a hydrosilylation catalyst is not used, for example, it is preferable to perform heating at a temperature of 100° C. This is because, if the temperature is lower than 100° C. unreacted alkoxysilyl groups and hydrosilyl groups tend to remain. In addition, for example, when heating is performed at about 200° C. or higher and 300° C. or lower, the heated cured product can be easily obtained.

In addition, when a catalyst for a hydrosilylation reaction is used, a cured product can be obtained at a lower temperature (for example, room temperature to 200° C., preferably 50° C. to 150° C., and more preferably 100° C. to 150° C.). The curing time in this case is generally, 0.05 to 24 hours, and preferably 0.1 to 5 hours. In the presence of a catalyst, if the temperature is 100° C. or higher, a cured product obtained by a hydrolysis/polycondensation and hydrosilylation reaction can be sufficiently obtained.

A catalyst for a hydrosilylation reaction may be group 8 to group 10 metals, such as cobalt, nickel, ruthenium, rhodium, palladium, iridium and platinum, and organometallic complexes, metal salts, metal oxides, and the like, of these metals. A platinum-based catalyst is generally used. Examples of platinum-based catalysts include cis-PtCl₂(PhCN)₂, platinum-carbon, a platinum complex in which 1,3-divinyltetramethyldisiloxane is coordinated (Pt(dvs)), a platinum vinylmethyl cyclic siloxane complex, a platinum carbonyl-vinylmethyl cyclic siloxane complex, diplatinum tris(dibenzylideneacetone), chloroplatinic acid, bis(ethylene)tetrachlorodiplatinum, cyclooctadienedichloroplatinum, bis(cyclooctadiene)platinum, bis(dimethylphenylphosphine)dichloroplatinum and tetrakis(triphenylphosphine)platinum. Of these, a platinum complex in which 1,3-divinyltetramethyldisiloxane is coordinated (Pt(dvs)), a platinum vinylmethyl cyclic siloxane complex or a platinum carbonyl-vinylmethyl cyclic siloxane complex is particularly preferred. Moreover, Ph denotes a phenyl group. The usage quantity of the catalyst is preferably 0.1 ppm by mass to 1000 ppm by mass, more preferably 0.5 to 100 ppm by mass, and further preferably 1 to 50 ppm by mass, relative to the amount of the present silsesquioxane derivative.

When a catalyst for a hydrosilylation reaction is used, a hydrosilylation reaction inhibitor may be added in order to inhibit gelation of the present silsesquioxane derivative to which the catalyst is added and improve the storage stability. Examples of hydrosilylation reaction inhibitors include methyl vinyl cyclotetrasiloxane, acetylene alcohols, siloxane-modified acetylene alcohols, hydroperoxide, and hydrosilylation reaction inhibitors containing nitrogen atoms, sulfur atoms or phosphorus atoms.

A process of curing the present silsesquioxane derivative may be performed in air regardless of whether a catalyst is provided, and may be performed in an inert gas atmosphere such as nitrogen gas or under a reduced pressure.

(Thermal Conductivity of Present Cured Product)

The thermal conductivity of the present cured product at 25° C. is, for example, 0.22 W/mk or more. In addition, for example, the thermal conductivity is 0.23 W/mk or more, and for example, 0.24 W/mk or more, and for example, 0.25 W/mk or more, and for example, 0.26 W/mk or more.

Here, the molded product (cured product) of the present silsesquioxane derivative can be obtained by the following method. For example, 20 mg of a platinum catalyst is added dropwise to 1 g of the present silsesquioxane derivative, and the mixture is stirred well. The obtained solution is transferred to an alumina crucible, heated in an air flow oven at 150° C. for 1 hour to obtain a cured product, which is used for the following evaluation. Here, the amount of the present silsesquioxane derivative collected and the amount of the platinum catalyst collected can be appropriately changed according to the size of a required measurement sample while maintaining the amount ratio.

The thermal conductivity λ (W/m·K) can be calculated using values of the density ρ (g/cm³), the specific heat c (J/g·K), and the thermal diffusivity α (mm²/s) based on the following formula a.

λ=α·ρ·c (a)

The density is calculated using the following formula b from values measured by an electronic balance of the mass in air and pure water according to Archimedes' principle. In the formula. M indicates the mass.

$$\begin{matrix}[ Math . 1 ] & \\ {ρ}_{sample} = \frac{{ρ}_{water} \cdot {M}_{air}}{{M}_{air} - {M}_{water}} & ( b )\end{matrix}$$

Here, measurement is performed at 25° C., and for the density of pure water at 25° C., the value (997.062) published on the website of Ryutai Kogyo Co., Ltd. (https://www.ryutai.co.jp/shiryou/liquid/water-mitsudo-1.htm) is used.

The specific heat is measured using DSC (Q100 commercially available from TA Instruments), and an alumina powder (AKP-30 commercially available from Sumitomo Chemical Company, Ltd.) is used as a standard substance at a specific heat of 0.78 (J/g·K). The measurement is performed for each of an empty container, a standard substance, and a test sample at a temperature rise rate of 10° C./min, the specific heat can be calculated by the formula c using a difference H between each heat flow (mW) of the standard substance and the test sample at 25° C. and a heat flow of the empty container, and the mass M during measurement.

$$\begin{matrix}[ Math . 2 ] & \\ {c}_{sample} = \frac{{H}_{sample}}{{H}_{ref}} \cdot \frac{{M}_{ref}}{{M}_{sample}} \cdot {c}_{ref} & ( c )\end{matrix}$$

The thermal diffusivity is measured by a laser flash method (LFA-467 commercially available from Netzsch) at 25° C. As a sample, a molded product (cured product) obtained by molding the present silsesquioxane derivative into a size of 1.2 cm×1.2 cm and a thickness of 0.5 to 1 mm is used. In addition, the surface of the sample is coated with a carbon spray in order to prevent laser reflection during measurement. The measurement is performed three times for one sample, and the average value thereof can be used as the thermal diffusivity for calculation of the thermal conductivity.

The heat resistance of the present cured product can be evaluated using a simultaneous differential thermal weight measurement (TG/DTA) device or the like. For example, the cured product is weighed out in a Pt pan, heated in air at 10° C./min, and the weight and the heat generation behavior are evaluated. As the measuring device, EXSTAR6000 TG/DTA 6300 (commercially available from Seiko Instruments Inc.) or an equivalent thereof can be used.

It is preferable that the present cured product have any of these various characteristics.

The present silsesquioxane derivative can be cured in various forms. For example, since the present silsesquioxane derivative is a liquid substance having a viscosity at 25° C. of 100,000 mPa·s or less, it can be directly applied to a substrate for curing, or it can be used after being diluted with a solvent as necessary. When a solvent is used, a solvent in which the present silsesquioxane derivative is dissolved is preferable, and examples thereof include various organic solvents such as an aliphatic hydrocarbon solvent, an aromatic hydrocarbon solvent, a chlorinated hydrocarbon solvent, an alcohol solvent, an ether solvent, an amide solvent, a ketone solvent, an ester solvent, and a cellosolve solvent. When a solvent is used, it is preferable to volatilize the solvent contained before heating is performed for curing the silsesquioxane derivative. The solvent may be volatilized in air, in an inert gas atmosphere, or under a reduced pressure. Heating may be performed for volatilizing the solvent, and the heating temperature in this case is preferably lower than 200° C., and more preferably 50° C. or higher and 150° C. or lower. In another method of producing the present cured product, the silsesquioxane derivative can be partially cured by heating it at 50° C. or higher and lower than 200° C. or 50° C. or higher and 150° C. or lower, and this can be used as a solvent volatilization process.

Various additives may be added to the present silsesquioxane derivative when it is subjected to curing. Examples of additives include reactive diluents such as tetraalkoxysilane and trialkoxysilanes (trialkoxysilane, trialkoxyvinylsilane, etc.). These additives are used as long as the thermal conductivity and the heat resistance of the obtained present cured product are not impaired.

(Insulation Element, Method of Producing Same, Structure and Method of Producing the Same)

The insulation element disclosed in this specification contains the present cured product and a thermally conductive filler. The insulation element can be obtained by, for example, curing a thermosetting composition containing a thermally conductive filler. The insulation element typically has a form of a matrix of the present cured product with a thermally conductive filler.

The insulation element can be obtained, for example, by preparing a thermosetting composition (mixture) by mixing the present silsesquioxane derivative with a thermally conductive filler, and preparing a cured product by treating the mixture at a curing treatment temperature of the present silsesquioxane derivative. As the mixing ratio of the present silsesquioxane derivative and the thermally conductive filler in this composition, the ratio already described in the present composition can be used. In addition, when the mixture is prepared, as necessary, a solvent such as an appropriate alcohol is used, and thus mixing can be easily performed.

The heat treatment process can have various forms as necessary. That is, in the heat treatment, a method of imparting a desired 3D form to a cured product to be obtained can be used, and as will be described below, a heat treatment can also be performed by performing supply to fill an insulating part of the insulation target in a layer shape, a film shape, a recess or the like.

The 3D shape of the insulation element is not particularly limited, and a form of a film, a sheet or the like can be used. In addition, as a molding method or the like, a general coating method such as casting, a spin coating method, and a bar coating method can be used. A molding method using a mold can also be used.

For example, in the case of a sheet shape or a film shape, the insulation element thus obtained is supplied as a cured product to the insulating part of the insulation target of various electronic components and other layers are additionally laminated as necessary, and thereby a structure can be obtained. In addition, the present composition can be in-situ cured at an insulating part of the insulation target to obtain a structure including an insulation element. According to the former method, since the molded product is formed in a sheet shape or the like in advance, it is possible to constitute heat dissipation without a heat treatment, including the insulation target. In addition, according to the latter method, since the present composition can be supplied to the insulating part depending on the fluidity of the present silsesquioxane derivative, it can be applied to various shapes and fine parts. Examples of structures include an insulating material such as an insulating substrate, a laminate substrate, and a semiconductor device.

The particle size such as the median diameter of the thermally conductive filler in the heat dissipation structure thus obtained is not particularly limited, but in order to efficiently exhibit the thermal conductivity, a relative ratio of the median diameter to the thickness of the heat dissipation structure composed of a cured product containing thermally conductive fillers and silsesquioxane derivatives is preferably 1% or more, more preferably 5% or more, still more preferably 7% or more, and particularly preferably 10% or more.

(Other Elements and Other Structures)

When the present composition is used as an adhesive composition, the present cured product can form a bonding element such as a bonding material without being limited to the insulation element. In addition, when the present composition is used as a binder composition, it is possible to form an internal element, for example, a covering element such as a coating material that may contain an appropriate filler and a filling agent which is a matrix that may contain a filler.

The shape and the like of the bonding element are not particularly limited, and examples of shapes include a layer shape, and examples of application destinations include a structure in which a silsesquioxane derivative is applied as a bonding material in the related art. The shape and the like of the covering element and the internal element are not particularly limited, and examples of shapes include a layer shape, and examples of application destinations include a structure in which a cured product of a silsesquioxane derivative is applied as a coating material or a filling agent in the related art.

In addition, when an adhesive composition is supplied, provided and cured with respect to a part (bonding target part) of any structure for which bonding is required, it is possible to provide a structure including a bonding element. In addition, it is also possible to provide a structure including a bonding element by supplying the pre-cured present cured product to a bonding target part. Similarly, when a cured product of a binder composition or a cured product obtained by in-situ curing a binder composition is supplied to a part (covering target part) of any structure for which covering is required or a part (filling target part) for which filling is required, it is possible to obtain a structure including a covering element and a filing element.

### EXAMPLES

This invention will now be explained in further detail through the use of embodiments. However, the present invention is in no way limited to these embodiments. Moreover, “Mn” and “Mw” denote number average molecular weight and weight average molecular weight respectively, and molecular weights are calculated using standard polystyrene from retention time when separation is carried out using gel permeation chromatography (hereinafter abbreviated to “GPC”) using connected GPC columns (“TSK gel G4000HX” and “TSK gel G2000HX” (model names, produced by Tosoh Corporation)) at 40° C. in a toluene solvent. In addition, ¹H-NMR analysis of the obtained silsesquioxane derivative, the sample was dissolved in deuterochloroform, and it was confirmed that the structure was as desired.

### Example 1

(Synthesis of Silsesquioxane Derivative)

In this example, the silsesquioxane derivative was synthesized by the following operation. The general formula and substituents of the synthesized silsesquioxane derivative are shown below.

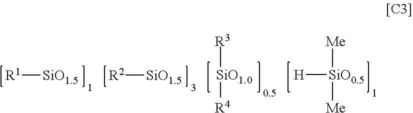

Silsesquioxane derivative 1: R¹=vinyl group, R², R³=Me
Silsesquioxane derivative 2: R¹=allyl group, R², R³=Ph

### Synthesis Example 1: Silsesquioxane Derivative 1

In a 200 ml 4-neck round-bottom flask including a thermometer, a dropping funnel, and a stirring blade, vinyltrimethoxysilane (7.4 g, 50 mmol), methyltriethoxysilane (26.7 g, 150 mmol), dimethoxydimethylsilane (3.0 g. 25 mmol), 1,1,3,3-tetramethyldisiloxane (3.4 g, 25 mmol), xylene (15 g), and 2-propanol (15 g) were weighed out and stirred well in a water bath at about 20° C. A solution prepared by separately mixing a 1 mol/L hydrochloric acid aqueous solution (0.45 g, 4.4 mmol), pure water (11.4 g), and 2-propanol (4.5 g) was added dropwise thereto from the dropping funnel for about 1 hour, and stirring additionally continued at room temperature overnight. The solvent was removed from the obtained solution under vacuum at 60° C., and 19 g of a silsesquioxane derivative 1 was obtained as a colorless and transparent liquid (yield 100%).

### Synthesis Example 2: Silsesquioxane Derivative 2

32 g of a silsesquioxane derivative 2 was obtained as a colorless and transparent liquid in the same operation as in silsesquioxane derivative 1 except that phenyltrimethoxysilane (29.7 g, 150 mmol) was used in place of methyltriethoxysilane, and dimethoxydiphenylsilane (6.1 g, 25 mmol) was used in place of dimethoxydimethylsilane (yield 100%).

### Synthesis Examples 3 and 4

The following silsesquioxane derivatives 3 and 4 were synthesized as Comparative Examples 1 and 2. The chemical structures of these silsesquioxane derivatives had the following substituent in the general formula described in Example 1, and each of them was synthesized by the following method.

Silsesquioxane derivative 3: R¹=vinyl group, R²=H, R³=Me
Silsesquioxane derivative 4: R¹=allyl group, R²=H, R³=Me

The silsesquioxane derivative 3 was synthesized in the same operation as in Synthesis Example 1 except that triethoxysilane (24.6 g, 150 mmol) was used in place of methyltriethoxysilane in Synthesis Example 1 (yield 100%, Mw=3830). In addition, the silsesquioxane derivative 4 was synthesized in the same operation as in Synthesis Example 1 except that allyltrimethoxysilane (8.1 g, 50 mmol) was used in place of vinyltrimethoxysilane, and triethoxysilane (24.6 g, 150 mmol) was used in place of methyltriethoxysilane (yield 100%).

### Example 2

(Preparation and Evaluation of Cured Product)

When cured products of the silsesquioxane derivatives 1 to 2 of Synthesis Examples 1 to 2 synthesized in Example 1 were prepared under the following two conditions, and preliminarily evaluated according to the thermal conductivity and TG/DTA, since no difference was observed in the thermal behavior under these two conditions, the cured product obtained under the condition [1] using a catalyst at 150° C., which was more difficult to crack during curing, was evaluated as cured products of Production Examples 1 and 2. In addition, for the silsesquioxane derivatives 3 and 4, cured products of Comparative Production Examples 1 and 2 using the condition [1] were prepared and evaluated.

[1] 150° C. Catalyst Used

20 mg of a platinum catalyst (SIP 6829.2 commercially available from Gelest) was added dropwise to 1 g of each silsesquioxane derivative synthesized in Example 1, and the mixture was stirred well. The obtained solution was transferred to an alumina crucible and heated in an air flow oven at 150° C. for 1 hour to obtain a cured product.

[2] 230° C. No Catalyst Used

1 g of each silsesquioxane derivative synthesized in Example 1 was weighed out in an alumina crucible, and heated stepwise in an air flow oven at 120° C. for 2 hours, at 180° C. for 2 hours, at 230° C. for 2 hours to obtain a cured product.

Here, as Comparative Example 3, a cured product using an epoxy resin was prepared by the following method. 0.8 g of a bisphenol A type epoxy resin (jER828, commercially available from Mitsubishi Chemical Corporation) and 0.2 g of DDM (diaminodiphenylmethane, commercially available from Tokyo Chemical Industry Co., Ltd.) were used, these were weighed out in a 20 ml eggplant flask, 5 g of acetone was added and dissolved, and the acetone was then removed under vacuum. The obtained oily substance was transferred to an alumina crucible, and heated in an air flow oven at 150° C. for 2 hours to obtain a cured product.

The TG/DTA, the density, the specific heat, the thermal diffusivity and the thermal conductivity of the obtained cured products of Production Examples 1 and 2 and Comparative Production Examples 1 to 3 were measured. Here, the measurement methods were as follows.

(TG/DTA)

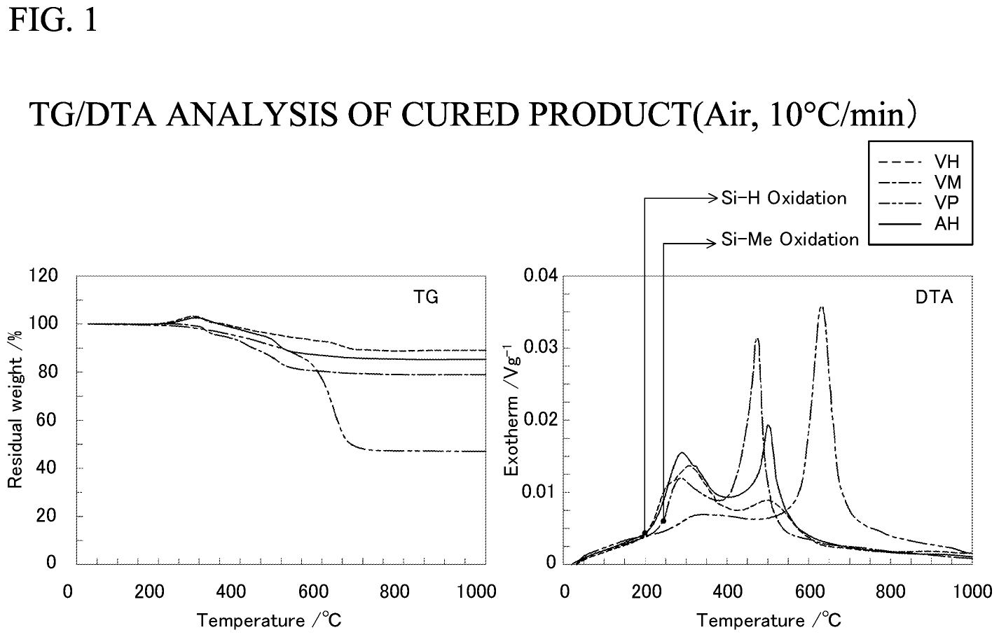

The cured product of the silsesquioxane derivative was heated from 30° C. to 1,000° C. and the thermal weigh reduction rate during that period was evaluated. Specifically, using a thermal analyzing device (EXSTAR6000 TG/DTA 6300 commercially available from Seiko Instruments Inc.), the cured product was weighed out in a Pt pan, heated in air at a temperature rise rate of 10° C./min from 30° C. to 1,000° C., and the weight and heat generation behavior during that period were evaluated. The results are shown in FIG. 1.

(Density)

The density is calculated using the following formula b from values measured by an electronic balance of the mass in air and pure water according to Archimedes' principle. In the formula. M indicates the mass. The results are shown in Table 1.

$$\begin{matrix}[ Math . 3 ] & \\ {ρ}_{sample} = \frac{{ρ}_{water} \cdot {M}_{air}}{{M}_{air} - {M}_{water}} & ( b )\end{matrix}$$

Here, measurement is performed at 25° C., and for the density of pure water at 25° C., the value (997.062) published on the website of Ryutai Kogyo Co., Ltd. (https://www.ryutai.co.jp/shiryou/liquid/water-mitsudo-1.htm) is used.

(Specific Heat)

The specific heat was measured using DSC (Q100 commercially available from TA Instruments), and an alumina powder (AKP-30 commercially available from Sumitomo Chemical Company, Ltd.) was used as a standard substance at a specific heat of 0.78 (J/g·K). The measurement was performed for each of an empty container, a standard substance, and a test sample at a temperature rise rate of 10° C./min, and the specific heat was calculated by the formula c using a difference H between each heat flow (mW) of the standard substance and the test sample at 25° C. and a heat flow of the empty container, and the mass M during measurement. The results are shown in Table 1.

$$\begin{matrix}[ Math . 4 ] & \\ {c}_{sample} = \frac{{H}_{sample}}{{H}_{ref}} \cdot \frac{{M}_{ref}}{{M}_{sample}} \cdot {c}_{ref} & ( c )\end{matrix}$$

(Thermal Diffusivity)

The thermal diffusivity was measured by a laser flash method (LFA-467 commercially available from Netzsch) at 25° C. As a sample, a molded product obtained by molding the present silsesquioxane derivative into a size of 1.2 cm×1.2 cm and a thickness of 0.5 to 1 mm was used. In addition, the surface of the sample was coated with a carbon spray in order to prevent laser reflection during measurement. The measurement was performed three times for one sample, and the average value thereof was used as the thermal diffusivity for calculation of the thermal conductivity. The results are shown in Table 1. Here, the thermal diffusivity was a value measured in the thickness direction of the molded article.

(Thermal Conductivity)

For the thermal conductivity λ (W/m·K), the thermal conductivity at 25° C. could be calculated using values of the density ρ (g/cm³), the specific heat c (J/g·K), and the thermal diffusivity α (mm²/s), based on the following formula a. The results are shown in Table 1. Here, the thermal conductivity was calculated using the thermal diffusivity of the molded article, and corresponded to the value in the thickness direction of the molded article.

λ=α·ρ·c (a)

As shown in FIG. 1, in Comparative Production Example 1 and Comparative Production Example 2, which were cured products of silsesquioxane derivatives containing H as R², heat generation was observed around 200° C., but in Production Example 1 and Production Example 2 which were cured products of the silsesquioxane derivatives 1 and 2 having a methyl group and a phenyl group as R², no significant heat generation was observed up to a higher temperature. The heat generation observed here indicates the occurrence of an oxidation reaction, and it can be said that, in Production Examples 1 and 2, oxidation during heating was less likely to occur compared to Comparative Production Examples 1 and 2. That is, it can be understood that, when R² has no H, it can withstand use at a higher temperature or for a long time.

For the thermal conductivity, as shown in Table 1, it was found that Production Examples 1 and 2 and Comparative Production Examples 1 and 2, which were cured products of silsesquioxane derivatives, all had higher thermal conductivity than the epoxy resin cured product of Comparative Production Example 3, and all had a high thermal conductivity. Generally, it was difficult to improve the thermal conductivity of the resin. On the other hand, the cured products of the silsesquioxane derivatives 1 and 2 of Production Examples 1 and 2 exhibited extremely high thermal conductivity of 126% and 135%, respectively, with respect to the thermal conductivity of the epoxy resin of Comparative Production Example 3.

In addition, Production Examples 1 and 2 exhibited higher thermal conductivity of 106% and 114%, respectively, compared with the thermal conductivity (0.231 W/mK on average) of Comparative Production Examples 1 and 2, which were cured products of the silsesquioxane derivatives 3 and 4.

TABLE 1

| Production | Type of | | | Thermal | Thermal |
|---|---|---|---|---|---|
| Example of | silsesquioxane | | Specific heat | diffusivity | conductivity |
| cured product | derivative | Density (g/cm³) | (kJ/kg · K) | (mm²/s) | (W/m · K) |
| Production | 1 | 1.2 | 1.3 | 0.157 | 0.245 |
| Example 1 | | | | | |
| Production | 2 | 1.23 | 1.32 | 0.162 | 0.263 |
| Example 2 | | | | | |
| Comparative | 3 | 1.25 | 1.21 | 0.151 | 0.228 |
| Production | | | | | |
| Example 1 | | | | | |
| Comparative | 4 | 1.25 | 1.21 | 0.155 | 0.234 |
| Production | | | | | |
| Example 2 | | | | | |
| Comparative | — | 1.19 | 1.14 | 0.144 | 0.195 |
| Production | (epoxy resin) | | | | |
| Example 3 | | | | | |

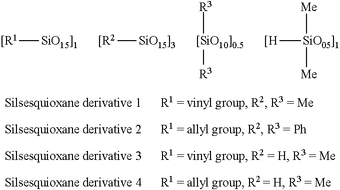

Since the cured products of Production Examples 1 and 2 also had excellent heat resistance, it can be understood that the silsesquioxane derivatives 1 and 2 of Synthesis Examples 1 and 2 were materials useful for applications such as an adhesive and a binder for a filler for which either high thermal conductivity, heat resistance or an insulating property or a combination thereof is required from the curing performance and the like inherent to the present silsesquioxane derivative in addition to insulation elements for which high thermal conductivity and heat resistance are required.

### Example 3

(Preparation of Composite (Thermosetting Product) of Silsesquioxane Derivative and the Like and Thermally Conductive Filler and Evaluation of Thermal Conductivity and the Like of Composite)

In the following method, using the silsesquioxane derivatives 1 and 3 synthesized in Example 1 and the epoxy resin used in Comparative Production Example 3 of Example 2, boron nitride (BN) powder (aggregate powder) and (amorphous) alumina (Al₂O₃) powder having various particle sizes (median diameters), crystallite sizes and selective orientation parameters, composites were synthesized according to the compositions in the following Table 2. Here, the BN powders having the same crystallite size and selective orientation parameter were of the same type.

[1] Preparation of Composite of Silsesquioxane Derivative and Thermally Conductive Filler

A total of 1 g of the silsesquioxane derivative 1 (SQ) and boron nitride powder or alumina powder was weighed out in a glass screw tube bottle so that the volume fractions shown in Table 2 were achieved. 1.5 g of 2-propanol (commercially available from FUJIFILM Wako Pure Chemical Corporation) was added thereto and the mixture was stirred using a rotation and revolution mixer at 1,800 rpm for 1 minute. The obtained solution was transferred to a 20 ml eggplant flask, and 2-propanol was removed in an evaporator to obtain a composite precursor. 0.1 g of the obtained composite precursor was weighed out, transferred to a powder molding mold (all carbide dice, 10 mm, commercially available from NPa System Co., Ltd.), and heated stepwise in a vacuum at 120° C. for 2 hours, at 180° C. for 2 hours, and at 230° C. 2 hours in air while applying a pressure of 60 MPa in a vacuum heating press machine, and finally, SQ/BN composites of Example Samples 1 to 6 and Comparative Example Sample 1 and a SQ/Al₂O₃ composite of Example Sample 4 were obtained.

[2] Preparation of Composite of Epoxy Resin and Thermally Conductive Filler

A total of 1 g of the epoxy resin oily substance used in Comparative Production Example 3 and boron nitride powder or alumina powder was weighed out in a glass screw tube bottle so that the volume fractions shown in Table 2 were achieved. 1.5 g of acetone was added thereto and the mixture was stirred using a rotation and revolution mixer at 1,800 rpm for 1 minute. The obtained solution was transferred to a 20 ml eggplant flask, and the acetone was removed in an evaporator to obtain a composite precursor. 0.1 g of the obtained composite precursor was weighed out and transferred to a powder molding mold (all carbide dice. 10 mm, commercially available from NPa System Co., Ltd.), and heated in a vacuum at 150° C. for 2 hours while applying a pressure of 60 MPa in a vacuum heating press machine, and finally, an epoxy/BN composite of Comparative Example Sample 2 and an epoxy/Al₂O₃ composite of Comparative Example Sample 3 were obtained.

TABLE 2

| | | | | | | | | Reduction rate | |
|---|---|---|---|---|---|---|---|---|---|
| | | | | | | | | of thermal | |
| | | | Type of thermally conductive filler, B | | | | | conductivity | Dielectric |
| | | Type of | Type | Crystallite | Selective | A:B | Thermal | after heating | strength |
| Type of | Configuration | silsesquioxane | (particle | size | orientation | (volume | conductivity | at 230° C. for | (kV/mm) |
| composite | of composite | derivative, A | size D₅₀) | (nm) | parameter | ratio) | (W/m · K) | 100 hours | 25° C./205° C. |
| Example | SQ/BN | 1 | BN | 189 | 0.800 | 3:7 | 7.5 | — | — |
| Sample 1 | | | (15 μm) | | | | | | |
| Example | SQ/BN | 1 | BN | 117 | 0.988 | 3:7 | 12.5 | — | — |
| Sample 2 | | | (75 μm) | | | | | | |
| Example | SQ/BN | 1 | BN | 112 | 0.976 | 3:7 | 14.1 | — | 61.6/51.0 |
| Sample 3 | | | (90 μm) | | | | | | |
| Example | SQ/Al₂O₃ | 1 | Al₂O₃ | — | — | 5:5 | — | less than 3% | — |
| Sample 4 | | | (amorphous) | | | | | | |
| Example | SQ/BN | 1 | BN | 99 | 0.880 | 3:7 | 11.0 | — | — |
| Sample 5 | | | (90 μm) | | | | | | |
| Example | SQ/BN | 1 | BN | 151 | 0.997 | 3:7 | 15.0 | — | — |
| Sample 6 | | | (40 μm) | | | | | | |
| Comparative | SQ/BN | 3 | BN | 117 | 0.988 | 3:7 | 9.6 | — | — |
| Example | | | (75 μm) | | | | | | |
| Sample 1 | | | | | | | | | |
| Comparative | Epoxy/BN | — | BN | 189 | 0.800 | 3:7 | 4.4 | — | — |
| Example | | (epoxy | (15 μm) | | | | | | |
| Sample 2 | | resin) | | | | | | | |
| Comparative | Epoxy/Al₂O₃ | — | Al₂O₃ | — | — | 5:5 | — | 15% | — |
| Example | | (epoxy | (amorphous) | | | | | | |
| Sample 3 | | resin) | | | | | | | |

BN (15 μm): median diameter about 15 μm
BN (75 μm): median diameter about 75 μm
BN (90 μm): median diameter about 90 μm

Here, the median diameter of the boron nitride powder was obtained by creating a particle size distribution of the thermally conductive fillers based on the volume using a laser diffraction scattering type particle size distribution measuring device.

X-ray diffraction (XRD) was measured under the following conditions.

Device: D8Advance (Bruker)

X-ray source: Cu Kα (λ=1.54 Å), 40 kV, 40 mA
Measurement range: 20 to 90 degrees
Optical system: concentration method

The selective orientation parameter and the crystallite size were obtained by refining the diffraction pattern measured and obtained by the above X-ray diffraction method according to the Rietveld method. For Rietveld analysis, TOPAS ver.4.2 (commercially available from Bruker) was used. The selective orientation was corrected using the selective orientation function of March-Dollase for the (002) plane.

<Thermal Conductivity of Composite>

Table 2 also shows the results obtained by calculating the thermal conductivity at 25° C. of the obtained composites in the same manner as in Example 2. It is thought that, even if the boron nitride powder having high thermal conductivity had various particle size distributions, the present silsesquioxane derivative could be favorably dispersed.

In addition, comparing Example Sample 2 and Comparative Example Sample 1, even though the same thermally conductive filler was used, the thermal conductivity of Example Sample 2 was 130% or more of that of Comparative Example Sample 1. This is because the thermal conductivity of the silsesquioxane derivative 1 itself of Production Example 1 used in Example Sample 2 was merely 107.5% of that of the silsesquioxane derivative 3 of Comparative Production Example 1 used in Comparative Example Sample 1 and thus it can be understood that a combination of the silsesquioxane derivative of the example and such a thermally conductive filler exhibited a synergistic effect.

In addition, focusing on the crystallite size and the selective orientation parameter of the thermally conductive filler, it can be clearly understood that the thermal conductivity of the composite tended to be larger as the crystallite size was larger and the selective orientation parameter was closer to 1.

That is, focusing on the crystallite size and the selective orientation parameter of Example Samples 1 to 3 and 5 and 6, it can be understood that, even if the silsesquioxane derivatives were the same, depending on selection of the crystallite size and the selective orientation parameter of the thermally conductive filler, the thermal conductivity changed up to about a maximum of double (the thermal conductivity of Example Sample 1 was 7.5, whereas the thermal conductivity of Example Sample 6 was 15.0).

In addition, it can be understood that, comparing Example Samples 3 and 5 using BN powders having the same median diameter (90 tan) but having different crystallite sizes and selective orientation parameters, the thermal conductivity increased as the crystallite size of the thermally conductive filler such as boron nitride used increased and the selective orientation parameter was closer to 1.

Furthermore, it can be understood that, comparing Example Samples 5 and 6, the thermal conductivity increased as the crystallite size of the thermally conductive filler such as boron nitride used was larger and the selective orientation parameter was closer to 1 (the thermal conductivity of Example Sample 5 was 11.0, whereas the thermal conductivity of Example Sample 6 was 15.0).

In addition, focusing on the thermal conductivity of Example Samples 1 to 3 and 5 and 6 and the selective orientation parameter of the BN powder used, it can be understood that there was a strong relationship between a tendency of the selective orientation parameter of the BN powder to be closer to 1 and a tendency of the thermal conductivity of the sample to increase. On the other hand, focusing on the crystallite size of the BN powder used for the same sample, it can be understood that a tendency of the crystallite size to increase and a tendency of the thermal conductivity of the sample to increase were not necessarily strongly related. That is, it can be understood that the thermal conductivity of the silsesquioxane derivative composite was strongly dependent on the selective orientation parameter of the thermally conductive filler used (particularly, it was clear in comparison between Example Sample 1 and Example Samples 5 and 6).

In addition, a crystallite has a range that can be recognized as a single crystal (by XRD, TEM, etc.), and it is thought that, when the size thereof was larger, there were fewer crystal grain boundaries in particles, the phonon scattering frequency was lower, and the thermal conductivity was better. It can be said that the above results indicated that a larger crystallite size of the thermally conductive filler contributed to the thermal conductivity.

Here, based on the above results, it cannot be said that the median diameter itself of the thermally conductive filler used was strongly related to the increase in thermal conductivity. Generally, it is thought that powder particles having a selective orientation parameter closer to 1 were composed of secondary particles in which many primary particles were aggregated, and the size of the crystallite size was related to the size of the primary particles. In addition, it is thought that the dispersibility of the thermally conductive filler in the silsesquioxane derivative was related to the median diameter. With reference to Table 2 in consideration of the above, it can be understood that the median diameter of the thermally conductive filler was preferably about 20 μm to about 100 μm or less in some cases.

As shown in Table 2, comparing Example Sample 2 and Comparative Example Sample 1, it can be understood that the composite using the present silsesquioxane derivative exhibited higher thermal conductivity than the composite using a conventional silsesquioxane derivative. That is, when the silsesquioxane derivative 3 of Comparative Example 1 was used, the thermal conductivity was 9.6 W/mK, and on the other hand, when the silsesquioxane derivative 1 of Synthesis Example 1 was used, the thermal conductivity was 12.5 W/mK, which was a value 30% or more higher than that of the silsesquioxane derivative 3 of Comparative Example 1.

In addition, comparing Example Sample 1 and Comparative Example Sample 2, it can be understood that the present silsesquioxane derivative exhibited better thermal conductivity than the epoxy resin used in the related art. That is, when the silsesquioxane derivative 1 was used, the thermal conductivity was 7.5 W/mK, and on the other hand, when the epoxy resin was used, the thermal conductivity was a lower value, 4.4 W/mK. When the silsesquioxane derivative 1 was used, the measured density was the same as the theoretical density calculated from the volume fraction, and on the other hand, when the epoxy resin was used, the density was a value 10% lower than the theoretical density. That is, it can be said that voids having a volume of about 10% were generated in the composite. Therefore, it is thought that the silsesquioxane derivative had excellent wettability to boron nitride with respect to the epoxy resin.

<Heat Resistance in View of Thermal Conductivity of Composite>

For Example Sample 4 and Comparative Example Sample 3, heating was performed in an air flow oven at 230° C. for 100 hours, the thermal conductivity before and after heating was measured, and the change thereof was evaluated. Table 2 also shows the results of the value obtained by dividing the thermal conductivity after heating by the thermal conductivity before heating, subtracting the value from 1, and multiplying it by 100, as the “reduction rate.”

As shown in Table 2, when the present silsesquioxane derivative was used, the reduction rate was less than 3%, and on the other hand, when the epoxy resin was used, the reduction rate was about 15%. It can be understood that, since the present silsesquioxane derivative also had excellent oxidation resistance and heat resistance, and as a result, it had an effect of maintaining high thermal conductivity against heat. This indicates that the present silsesquioxane derivative had excellent heat resistance as a filler binder or adhesive.

<Dielectric Strength>

The composite of Example Sample 3 was subjected to a dielectric breakdown test at 25° C. and 205° C., and the dielectric strength was measured. In the dielectric breakdown test, YHTA/D-30K-2KDR (commercially available from YAMABISHI) was used as a control device, according to JIS C2110-1, boosting was performed at an applied voltage of 60 Hz AC at a 500 V/sec, and the voltage value when a current of 10 mA or more flowed was defined as a dielectric breakdown voltage. In addition, the insulation breakdown voltage value was divided by the thickness of a part of the sample in which breakdown occurred to obtain a dielectric strength. The test was performed in a silicone oil at 25° C. and 205° C., and both electrodes were 6 mmΦ bar electrodes. The results are also shown in Table 2.

As shown in Table 2, the dielectric strength was 61.6 kV/mm (25° C.) and 50.0 kV/mm (205° C.), and a high insulating property was exhibited regardless of the temperature. It can be understood that the present silsesquioxane derivative can form a very excellent heat-resistant insulating and highly thermally conductive material.

1. A silsesquioxane derivative represented by following Formula (1):
[C4]
[SiO_{4/2}]ₛ[R¹—SiO_{3/2}]ₜ[R²—SiO_{3/2}]ᵤ[H—SiO_{3/2}]ᵥ[R³₂—SiO_{2/2}]_{w}[H,R⁴₂—SiO_{1/2}]ₓ[R⁵₃—SiO_{1/2}]_{y} (1)
[in the formula, R¹ is a hydrosilylation-reactive organic group having a carbon-carbon unsaturated bond and having 2 to 30 carbon atoms, R², R³, R⁴ and R⁵ are each independently at least one selected from the group consisting of an alkyl group having 1 to 10 carbon atoms, an aryl group having 5 to 10 carbon atoms and an aralkyl group having 6 to 10 carbon atoms, t, u, w and x are a positive number, and s, v and y are 0 or a positive number].

2. The silsesquioxane derivative according to claim 1, wherein, in the Formula (1), u>v.

3. The silsesquioxane derivative according to claim 2, wherein, in the Formula (1), x>y.

4. The silsesquioxane derivative according to claim 1,
wherein, in the Formula (1),
0<t/(t+u+v+w+x+y)≤0.3,
0<u/(t+u+v+w+x+y)≤0.6,
0<w/(t+u+v+w+x+y)≤0.2, and
0≤y/(t+u+v+w+x+y)≤0.1.

5. The silsesquioxane derivative according to claim 4, wherein, in the Formula (1),
0<x/(t+u+v+w+x+y)≤0.3.

6. The silsesquioxane derivative according to claim 1, wherein, in the Formula (1), R² and R³ are same.

7. (canceled)

8. The silsesquioxane derivative according to claim 1, wherein, in the Formula (1), s=0 and v=0, t:u:w:x:y=0.8 or more and 2.2 or less: 1.5 or more and 3.6 or less: 0.25 or more and 0.6 or less: 0.8 or more and 2.2 or less: 0 or more and 0.6 or less, R¹ is a vinyl group, and R², R³ and R⁴ are a methyl group (where, when 0<y, R⁵ is a methyl group).

9. (canceled)

10. The silsesquioxane derivative according to claim 1, wherein a molar ratio of C/Si is larger than 0.9.

11. The silsesquioxane derivative according to claim 1, wherein a thermal conductivity of a cured product at 25° C. is 0.22 W/mK or more.

12. A thermosetting composition including the silsesquioxane derivative according to claim 1.

13. (canceled)

14. (canceled)

15. An insulating material composition including the silsesquioxane derivative according to claim 1, and a thermally conductive filler.

16. The insulating material composition according to claim 15, wherein the thermally conductive filler is a nitride.

17. The insulating material composition according to claim 16, wherein the nitride is boron nitride.

18. The insulating material composition according to claim 17, wherein the boron nitride has a selective orientation parameter of 0.800 or more and 1.200 or less, and wherein the boron nitride has a crystallite size of 50 nm or more and 300 nm or less.

19-22. (canceled)

23. The insulating material composition according to claim 15, wherein a content of the thermally conductive filler is 20 vol % or more and 95 vol % or less with respect to a total volume of the silsesquioxane derivative and the thermally conductive filler.

24. An insulation element including a cured product of the silsesquioxane derivative according to claim 1, and a thermally conductive filler.

25. A structure including the insulation element according to claim 24.

26. The structure according to claim 25, which is a semiconductor device.

27. The structure according to claim 26, wherein the semiconductor device includes a semiconductor element having a Si layer, a SiC layer or a GaN layer.

28. (canceled)

29. A method of producing a structure, the method including:
a step of supplying a cured product of a thermosetting composition containing the silsesquioxane derivative according to claim 1 and a thermally conductive filler to an insulation target; or
a step of supplying the thermosetting composition to the insulation target and then supplying the cured product to the insulation target by in-situ curing.
